(19) United States
(12) Patent Application Publication
(10) Pub. No.: US 2010/0025687 A1
(43) Pub. Date: Feb. 4, 2010

(54) IMAGE SENSOR AND METHOD FOR MANUFACTURING THE SAME

(76) Inventor: CHANG HUN HAN, Anyang-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/511,336

(22) Filed: Jul. 29, 2009

(30) Foreign Application Priority Data
Jul. 29, 2008 (KR) 10-2008-0074191
Oct. 14, 2008 (KR) 10-2008-0100579

(51) Int. Cl. H01L 31/0376; H01L 21/30

(52) U.S. Cl. 257/59; 438/73; 257/E31.047; 257/E21.211

(57) ABSTRACT

An image sensor and a method for manufacturing the same are provided. The image sensor comprises a readout circuitry, a first interlayer dielectric with an interconnection therein, a second interlayer dielectric, an image sensing device, and a contact plug. The readout circuitry is formed in a first substrate. The first interlayer dielectric is formed over the first substrate. The interconnection is electrically connected to the readout circuitry. The second interlayer dielectric is formed over the first interlayer dielectric. The image sensing device comprises a first laser annealed trench and is disposed over the second interlayer dielectric. The contact plug penetrates the first laser annealed trench and the second interlayer dielectric and electrically connects the image sensing device and the interconnection.

### CROSS-REFERENCE TO RELATED APPLICATIONS

This application claims the benefit under 35 U.S.C. §119 of Korean Patent Application Nos. 10-2008-0074191, filed Jul. 29, 2008, and 10-2008-0100579, filed Oct. 14, 2008, which are hereby incorporated by reference in their entireties.

### BACKGROUND

The present disclosure relates to an image sensor and a method for manufacturing the same.

An image sensor is a semiconductor device for converting an optical image into an electric signal. The image sensor may be roughly classified into a charge coupled device (CCD) image sensor and a complementary metal oxide semiconductor (CMOS) image sensor (CIS).

During the fabrication of image sensors, a photodiode may be formed in a substrate using ion implantation. As the size of a photodiode is reduced for the purpose of increasing the number of pixels without increasing chip size, the area of a light receiving portion is also reduced, thereby resulting in a reduction in image quality.

Also, since a stack height does not reduce as much as the reduction in the area of the light receiving portion, the number of photons incident to the light receiving portion is also reduced due to diffraction of light called Airy disk.

As an alternative to overcome this limitation, an attempt of forming a photodiode using amorphous silicon (Si), or forming a readout circuitry in a silicon (Si) substrate using a method such as wafer-to-wafer bonding, and forming a photodiode on and/or over the readout circuitry has been made (referred to as a three-dimensional (3D) image sensor). The photodiode is connected with the readout circuitry through a metal interconnection.

In the related art, a device separation process is performed to separate a device by pixel of the photodiode. However, when the device separation process is performed by etching a pixel boundary of the photodiode, a lattice mismatch generated in the boundary may cause a dangling bond, resulting in generation of a dark current. Particularly, in a structure where a photodiode is disposed at a side of a readout circuitry, an annealing process can be performed to compensate the dark current before an interconnection process. However, a high-temperature annealing process can not be performed when the photodiode is formed after the interconnection process.

Also, when a process of forming a contact plug that penetrates a photodiode (that is formed over the interconnection) in a related art is performed, a dark current may be generated due to a lattice mismatch of a photodiode surface that is etched in an etching process of the photodiode for forming the contact plug.

In addition, both the source and the drain of the transfer transistor are heavily doped with N-type impurities, a charge sharing phenomenon occurs. When the charge sharing phenomenon occurs, the sensitivity of an output image is reduced and an image error may be generated. Also, because a photo charge does not readily move between the photodiode and the readout circuitry, a dark current is generated and/or saturation and sensitivity is reduced.

### BRIEF SUMMARY

Embodiments provide an image sensor that can reduce a dark current at a pixel boundary or an etched surface of an image sensing device, and a method for manufacturing the same.

Embodiments also provide an image sensor where a charge sharing does not occur while increasing a fill factor and a method for manufacturing the same.

Embodiments also provide an image sensor that can minimize a dark current source and inhibit saturation reduction and sensitivity degradation by forming a smooth transfer path of a photo charge between a photodiode and a readout circuit, and a method for manufacturing the same.

In one embodiment, an image sensor comprises: a readout circuitry in a first substrate; a first interlayer dielectric over the first substrate; an interconnection in the first interlayer dielectric and electrically connected to the readout circuitry; a second interlayer dielectric over the first interlayer dielectric; an image sensing device comprising a first laser annealed trench, the image sensing device being disposed over the second interlayer dielectric; and a contact plug penetrating the first laser annealed trench and the second interlayer dielectric and electrically connecting the image sensing device and the interconnection.

In another embodiment, an image sensor comprises: a readout circuitry in a first substrate; an interlayer dielectric over the first substrate; an interconnection in the interlayer dielectric and electrically connected to the readout circuit; an image sensing device over the interconnection; a trench at a pixel boundary of the image sensing device; a second conductive ion implantation region laser-annealed on the sidewall of the trench; and a device separation region in the trench.

In still another embodiment, a method for manufacturing an image sensor comprises: forming a readout circuitry in a first substrate; forming a first interlayer dielectric over the first substrate; forming an interconnection in the first interlayer dielectric and electrically connected to the readout circuitry; forming a second interlayer dielectric over the interconnection; forming an image sensing device over the second interlayer dielectric; forming a first trench penetrating the image sensing device; performing a first laser annealing on a side wall of the first trench; forming a contact plug in the first laser annealed trench; and forming an insulating layer over the contact plug in the first trench.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of an image sensor according to an embodiment.

FIGS. 2 to 13 are cross-sectional views illustrating a method for manufacturing an image sensor according to a first embodiment.

FIG. 14 is a cross-sectional view of an image sensor according to a second embodiment.

FIG. 15 is a cross-sectional view of an image sensor according to a third embodiment.

FIGS. 16 to 22 are cross-sectional views illustrating a method for manufacturing the image sensor according to the third embodiment.

### DETAILED DESCRIPTION

Hereinafter, embodiments of an image sensor and a method for manufacturing the same will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

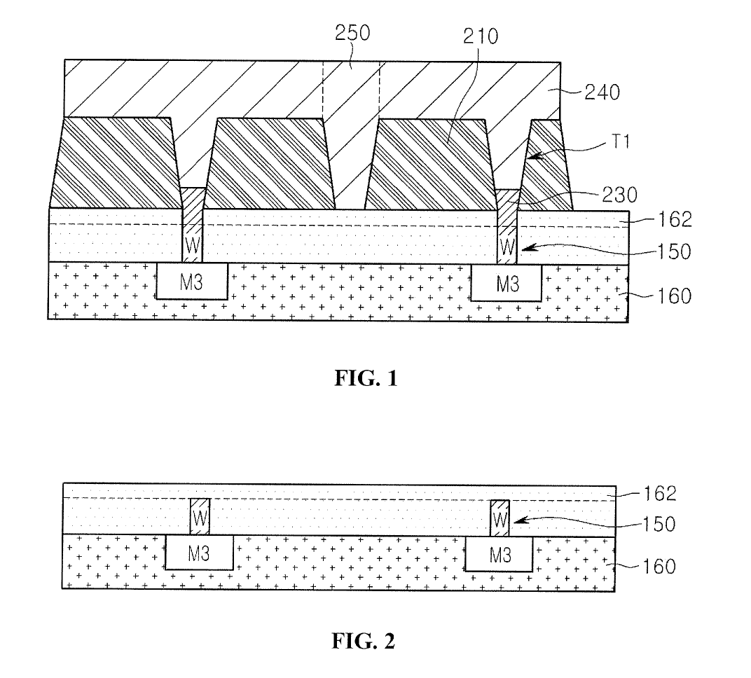

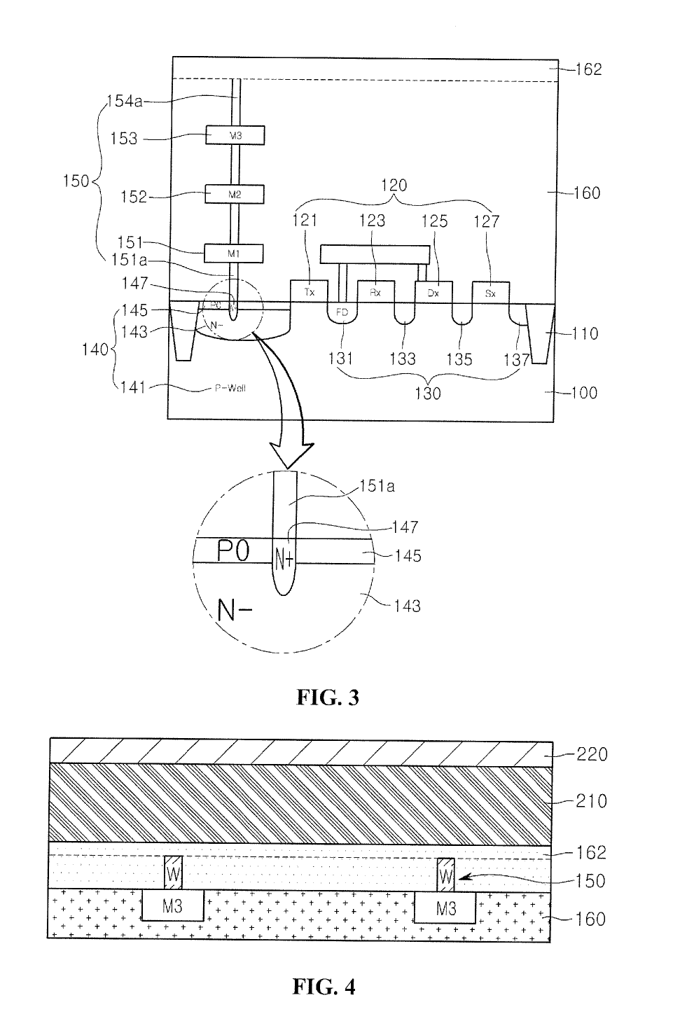

FIG. 1 is a cross-sectional view of an image sensor according to an embodiment. In the depicted embodiment, a first substrate (not shown) is provided with a first interlayer dielectric 160 and a second interlayer dielectric 162 having an interconnection 150 therein that is electrically connected to readout circuitry (not shown) formed in the first substrate. An image sensing device 210 is disposed over the second interlayer dielectric and includes a first laser annealed trench T1. The image sensing device 210 is electrically connected to the interconnection 150 through contact plug 230 penetrating the first laser annealed trench T1 and the second interlayer dielectric 162. FIG. 3 shows a detailed view of a first substrate in accordance with a first embodiment.

Referring to FIGS. 1 and 3, an image sensor according to the first embodiment comprises: a readout circuitry 120 in a first substrate 100; a first interlayer dielectric 160 over the first substrate 100; an interconnection 150 electrically connected to the readout circuitry over the first interlayer dielectric 160; a second interlayer dielectric 162 over the first interlayer dielectric 160; an image sensing device 210 comprising a first laser annealed trench T1, the image sensing device being disposed over the second interlayer dielectric 162; and a contact plug 230 penetrating the first laser annealed trench T1 and the second interlayer dielectric 162 and electrically connecting the image sensing device 210 and the interconnection 150.

The image sensing device 210 may be a photodiode, but, without being limited thereto, may be a photogate, or a combination of the photodiode and the photogate. Embodiments include a photodiode formed in a crystalline semiconductor layer as an example. However, embodiments are not limited thereto, and may include, for example, a photodiode formed in amorphous semiconductor layer.

Unexplained reference numerals in FIG. 1 will be described with reference to the drawings illustrating a method for manufacturing the image sensor below.

Hereinafter, a method for manufacturing the image sensor according to the first embodiment will be described with reference to FIGS. 2 to 13.

FIG. 2 is a cross-sectional view illustrating a first substrate 100 where an interconnection 150 is formed, and FIG. 3 is a detail view of the first substrate of FIG. 2. Hereinafter, detailed descriptions will be made with reference to FIG. 3.

As illustrated in FIG. 3, a first substrate 100 including an interconnection 150 and a readout circuitry 120 is prepared. For example, an active region is defined by forming a device separation layer 110 in the first substrate 100. The readout circuitry 120 may include a transfer transistor (Tx) 121, a reset transistor (Rx) 123, a drive transistor (Dx) 125, and a select transistor (Sx) 127. A floating diffusion region (FD) 131 and an ion implantation region 130 including a source/drain region 133, 135 and 137 for each transistor may be formed.

According to an embodiment, an electrical junction region 140 can be formed on the first substrate 100 and a first conductive connection 147 can be formed connected to the interconnection 150 at an upper part of the electrical junction region 140.

For example, the electrical junction region 140 may be a P-N junction 140, but is not limited thereto. For example, the electrical junction region 140 may include a first conductive type ion implantation layer 143 formed on a second conductive type well 141 or a second conductive type epitaxial layer, and a second conductive type ion implantation layer 145 formed on the first conductive type ion implantation layer 143. For example, as shown in FIG. 3, the P-N junction 140 may be a P0(145)/N−(143)/P−(141) junction, but embodiments are not limited thereto. The first substrate 100 may be a second conductive type substrate, but is not limited thereto.

According to an embodiment, the device is designed to provide a potential difference between the source and drain of the transfer transistor (Tx), thereby enabling the full dumping of a photo charge. Accordingly, a photo charge generated in the photodiode is dumped to the floating diffusion region, thereby increasing the output image sensitivity.

That is, as shown in FIG. 3, the electrical junction region 140 is formed in the first substrate 100 including the readout circuit 120 to provide a potential difference between the source and drain of the transfer transistor (Tx) 121, thereby implementing the full dumping of a photo charge.

Hereinafter, a dumping structure of a photo charge according to an embodiment will be described in detail.

In an embodiment, unlike a floating diffusion (FD) 131 node of an N+ junction, the P/N/P unction 140 of the electrical junction region 140 is pinched off at a predetermined voltage without an applied voltage being fully transferred thereto. This voltage is called a pinning voltage. The pinning voltage depends on the P0 (145) and N− (143) doping concentration.

Specifically, electrons generated in the photodiode 210 are transferred to the PNP junction 140, and they are transferred to the floating diffusion (FD) 131 node to be converted into a voltage when the transfer transistor (Tx) 121 is turned on.

The maximum voltage of the P0/N−/P− junction 140 becomes a pinning voltage, and the maximum voltage of the FD 131 node becomes Vdd minus the threshold voltage (Vth) of the reset transistor (Rx). Therefore, due to a potential difference between the source and drain of the Tx 131, without charge sharing, electrons generated in the photodiode 210 on the chip can be completely dumped to the FD 131 node.

That is, according to an embodiment, instead of an N+/P-well junction, a P0/N−/P− well junction is formed in a silicon substrate (Si-Sub) of the first substrate 100. A reason for this is that, in a 4-Tr active pixel sensor (APS) reset operation, a positive (+) voltage is applied to the N− region (143) in the P0/N−/P-well junction and a ground voltage is applied to the P0 region (145) and the P-well (141) and thus a P0/N−/P-well double junction generates a pinch-off at a predetermined voltage or higher like in a BJT structure. This is called a pinning voltage. Thus, a potential difference occurs between the source and drain of the Tx 121, thus making it possible to inhibit a charge sharing phenomenon due to full dumping of photocharges from N-well from to FD through Tx in a Tx on/off operation.

Thus, unlike the related art case of connecting a photodiode simply to an N+ junction, an embodiment of the present invention makes it possible to inhibit saturation reduction and sensitivity degradation.

A first conductive connection 147 can be formed between the photodiode and the readout circuit to create a smooth transfer path of a photo charge, thereby making it possible to minimize a dark current source and inhibit saturation reduction and sensitivity degradation.

To this end, the first embodiment may form an N+ doping region as a first conductive connection 147 for an ohmic contact on the surface of the P0/N−/P− junction 140. The N+ region (147) may be formed such that it pierces the P0 region (145) to contact the N− region (143).

The width of the first conductive connection 147 may be minimized to inhibit the first conductive connection 147 from being a leakage source. To this end, a plug implant may be performed after etching a contact hole for a first metal contact 151a, but embodiments are not limited thereto. As another example, an ion implantation pattern (not shown) may be formed, and the ion implantation pattern may be used as an ion implantation mask to form the first conductive connection 147.

That is, a reason why an N+ doping is locally performed only on a contact formation region as described in the first embodiment is to minimize a dark signal and implement the smooth formation of an ohmic contact. If the entire Tx source region is N+ doped like the related art, a dark signal may increase due to an Si surface dangling bond.

Next, an interlayer dielectric 160 may be formed on the first substrate 100, and an interconnection 150 may be formed. The interconnection 150 may include the first metal contact 151a, a first metal 151, a second metal 152, a third metal 153, and a fourth metal contact 154a, but embodiments are not limited thereto.

A second interlayer dielectric 162 is formed over the first interlayer dielectric 160. Referring to FIG. 4, an image sensing device 210 is formed over the second interlayer dielectric 162. For example, the image sensing device 210 may be a photodiode formed over a crystalline semiconductor layer. However, embodiments are not limited thereto, and may be, for example, an amorphous silicon-based photodiode. In an embodiment, the image sensing device 210 may be a photodiode including an N+ layer, an N− layer, and a P+ layer in a crystalline semiconductor layer.

In one embodiment, the image sensing device 210 may be formed on a second substrate (not shown) and then bonded to the second interlayer dielectric layer 162. Then, the second substrate is removed leaving the image sensing device 210 on the second interlayer dielectric layer 162.

A hard mask 220 may be formed over the image sensing device 210. For example, the hard mask 220 can be formed of an oxide, but is not limited thereto.

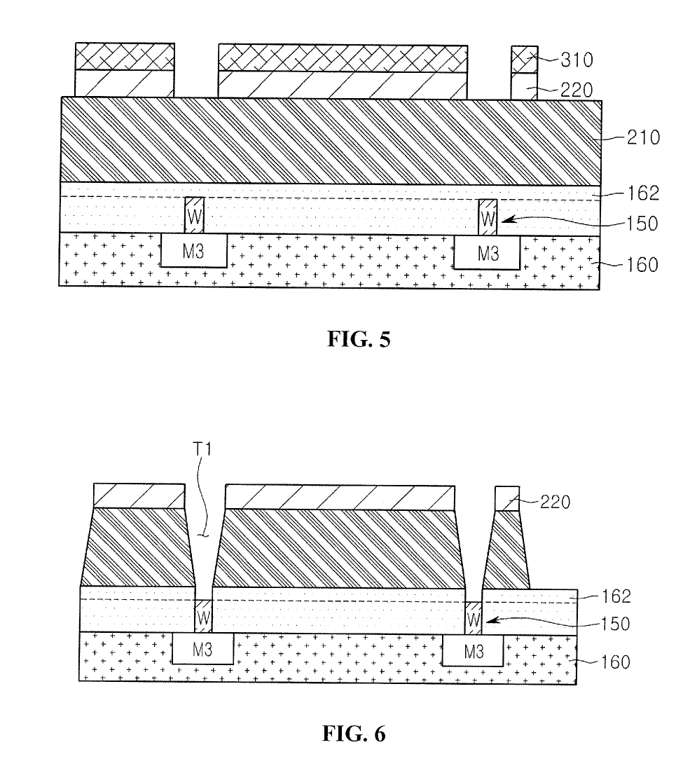

As illustrated in FIG. 5, a first photoresist pattern 310 is formed to define a contact plug. A portion of the hard mask 220 may be etched using the first photoresist pattern 310 as an etch mask.

Referring to FIG. 6, a first trench T1 penetrating the image sensing device 210 is formed. For example, the first trench T1 exposing the upper part of the interconnection 150 may be formed by etching the image sensing device 210 and the second interlayer dielectric 162 using the first photoresist pattern 310 and/or the hard mask 220 as an etch mask.

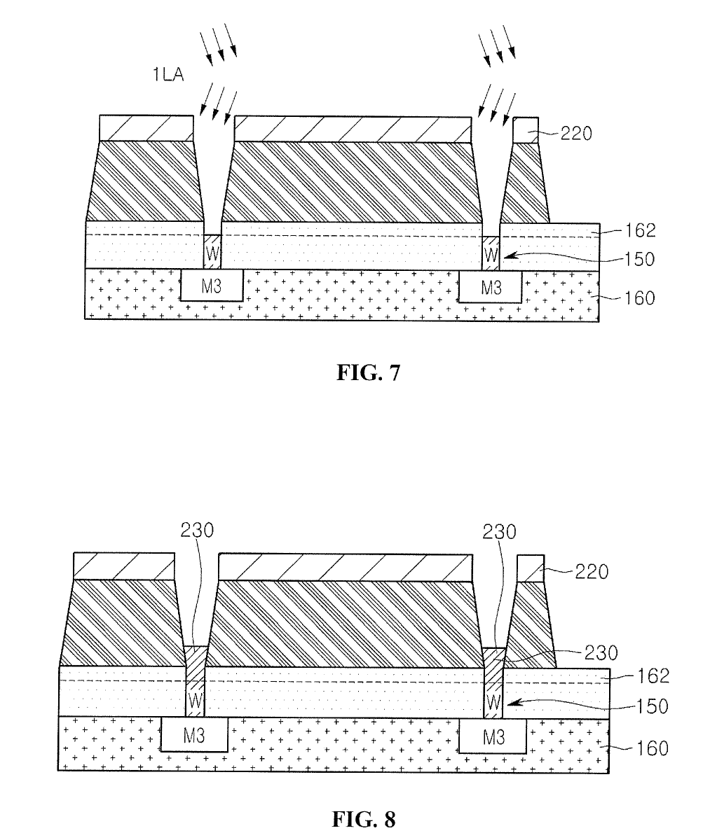

As illustrated in FIG. 7, a first laser annealing 1LA may be performed on the sidewalls of the first trench T1. For example, the first laser annealing 1LA may be performed using an energy of about 600 mJ/cm² to about 1200 mJ/cm².

According to an embodiment, the generation of a dark current may be inhibited by removing a dangling bond at an etched surface of the image sensing device 210, such as where the contact plug is to be formed, through a local laser annealing on the etched surface of the image sensing device where the crystalline continuity is broken.

As illustrated in FIG. 8, a contact plug 230 is formed in the first trench T1 where the first laser annealing was performed. According to an embodiment, after the first trench T1 is filled with a metal layer (not shown), the metal layer contacting a P+ layer region of the image sensing device 210 is removed to form the contact plug 230 through a blanket etch or an etch back. By removing the metal layer contacting the P+ layer region of the image sensing device, a short can be avoided.

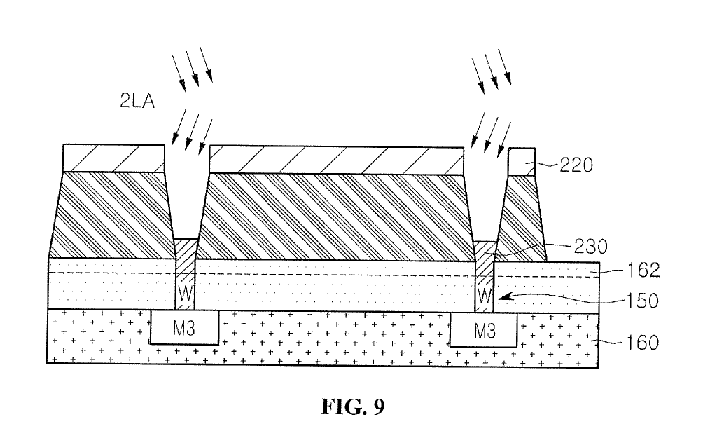

As illustrated in FIG. 9, after the formation of the contact plug 230, a second laser annealing 2LA may further be performed on the sidewalls of the first trench T1. According to an embodiment, the generation of a dark current may be inhibited by removing a dangling bond through a local laser annealing on an etched surface of the image sensing device 210, such as where the etching for a contact plug occurred and where a crystalline continuity is broken.

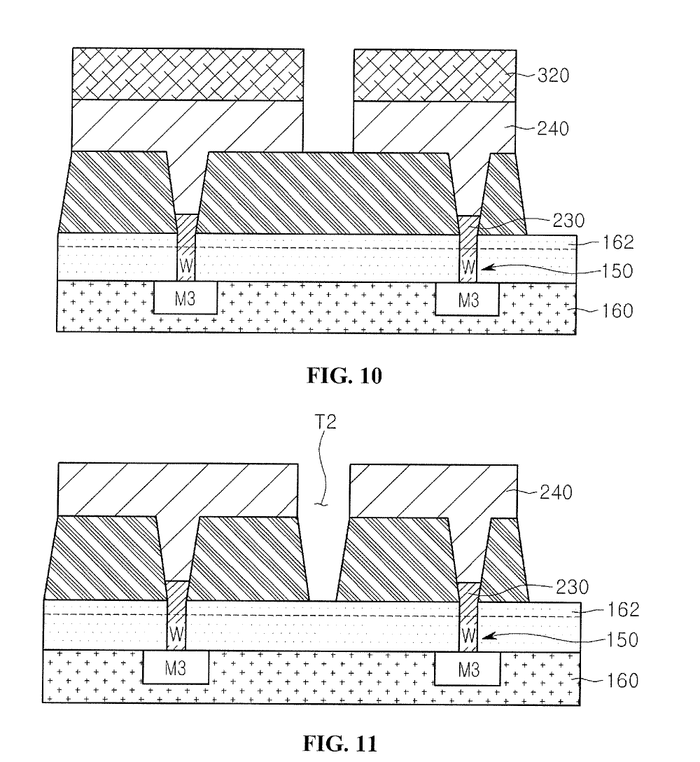

As illustrated in FIG. 10, a first insulating layer 240 filling the first trench T1 may be formed on the contact plug 130. Then, the first insulating layer 240 may be partially removed at a pixel boundary using a second photoresist pattern 320 as an etch mask.

Referring to FIG. 11, a second trench T2 may be formed at the pixel boundary using the second photoresist pattern 320 as an etch mask.

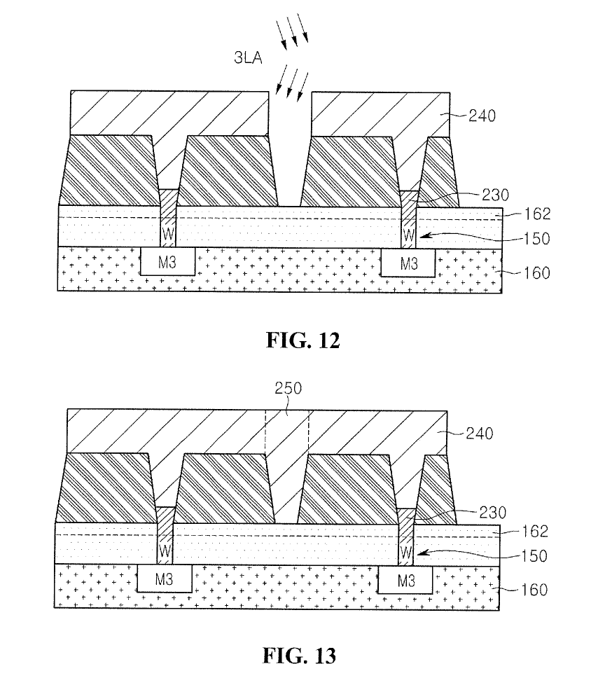

As illustrated in FIG. 12, a third laser annealing 3LA may be performed on the sidewalls of the second trench T2. The third laser annealing 3LA may be performed using an energy of about 600 mJ/cm² to about 1200 mJ/cm². According to an embodiment, the generation of a dark current may be inhibited by removing a dangling bond through a local laser annealing on an etched surface of the image sensing device 210.

Embodiments may further include forming a second conductive type ion implantation region (not shown) on the sidewalls of the second trench T2. For example, a P+ ion implantation region of high concentration (for example, using a dose of about 5×10¹²/cm² to about 5×10¹⁴/cm²) may be formed on the sidewall of the second trench T2.

Embodiments may further include damaging a surface lattice on the sidewall of the second trench T2 before forming the second conductive type ion implantation region on the sidewalls of the second trench T2. For example, the second conductive type ion implantation region may be thinly formed to secure the electrostatic capacity of the image sensing device. For this, after damaging the surface lattice by ion-implanting GeF₂ before an ion-implantation of the second conductive ion implantation region, B or BF₂ may be ion-implanted. Resulting lattice damage may be recovered by a laser annealing later.

A third laser annealing may be performed on the second conductive ion implantation region of the second trench T2. For example, the laser annealing may be performed using an energy of about 600 mJ/cm² to about 1200 mJ/cm² to activate the second conductive ion implantation region.

According to an embodiment, the generation of a dark current may be inhibited at a pixel boundary by removing a dangling bond through a formation of a thin P+ layer on an interface of the pixel boundary of the image sensing device where a crystalline continuity is broken, and a local laser annealing to activate the P+ layer.

As illustrated in FIG. 13, a device separation region 250 can be formed in the second trench T2 where the third layer annealing was performed. After this, a process for forming a contact for an upper ground and a process for depositing and patterning a conductor to connect the ground may be performed.

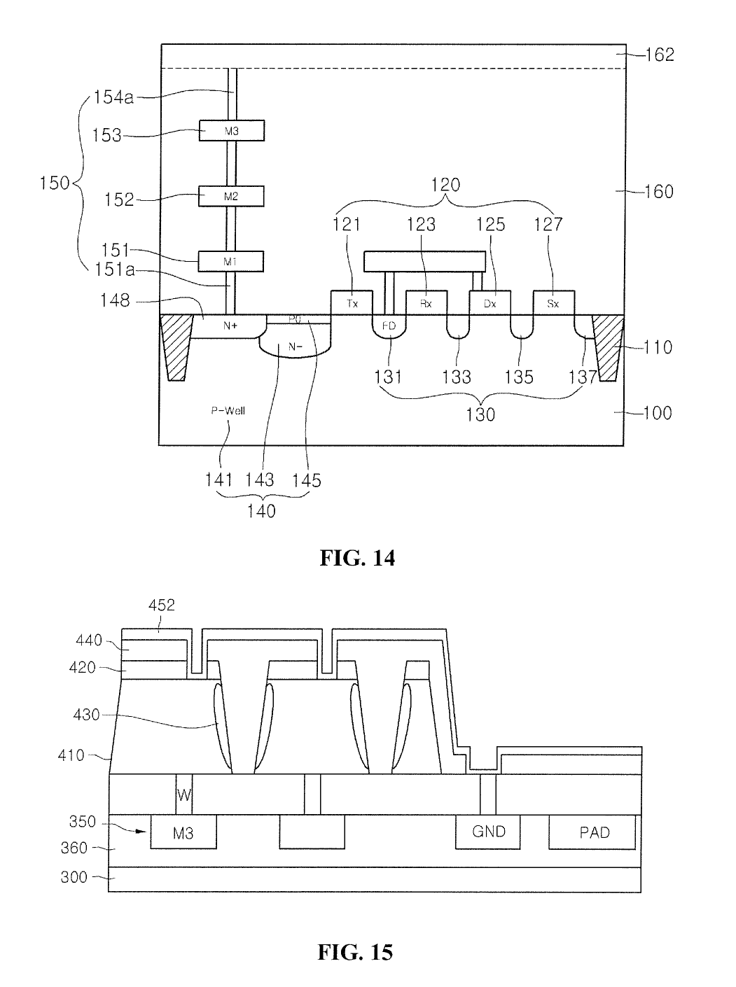

FIG. 14 is a cross-sectional view of an image sensor according to a second embodiment, and provides a detail view of a first substrate including an interconnection 150 formed therein.

Referring to FIGS. 1 and 14, an image sensor according to the second embodiment comprises: a readout circuitry 120 over a first substrate 100; a first interlayer dielectric 160 over the first substrate 100; an interconnection 150 electrically connected to the readout circuitry over the first interlayer dielectric 160; a second interlayer dielectric 162 over the first interlayer dielectric 160; an image sensing device 210 comprising a first laser annealed trench T1, the image sensing device 210 being disposed over the second interlayer dielectric 162; and a contact plug 230 penetrating the first laser annealed trench T1 and the second interlayer dielectric 162 and electrically connecting the image sensing device 210 and the interconnection 150.

The second embodiment may adopt the technical features of the first embodiment.

According to the second embodiment, for example, the generation of a dark current may be inhibited by removing a dangling bond through a local laser annealing on a pixel boundary and/or an etched surface for a contact plug of the image sensing device 210 where a crystalline continuity is broken.

According to the second embodiment, the generation of a dark current may be inhibited at a pixel boundary by removing a dangling bond through a formation of a thin P+ layer on an interface of the pixel boundary of the image sensing device where a crystalline continuity is broken, and a local laser annealing to activate the P+ layer.

According to the second embodiment, the device is designed to provide a potential difference between the source and drain of the transfer transistor (Tx), thereby enabling the full dumping of a photo charge.

According to the second embodiment, a charge connection region is formed between a photodiode and a readout circuit to create a smooth transfer path of a photo charge, thereby making it possible to minimize a dark current source and inhibit saturation reduction and sensitivity degradation.

Unlike the first embodiment, the first conductive connection 148 is formed at one side of the electrical junction region 140.

An N+ connection region 148 may be formed at a P0/N−/P− junction 140 for an ohmic contact. In this case, a leakage source may be generated during the formation process of an N+ connection region 148 and a M1C contact 151a. This is because an electric field (EF) may be generated over the Si surface due to operation while a reverse bias is applied to P0/N−/P− junction 140. A crystal defect generated during the contact formation process inside the electric field may become a leakage source.

Also, when the N+ connection region 148 is formed over the surface of P0/N−/P− junction 140, an electric field may be additionally generated due to N+/P0 junction 148/145. This electric field may also become a leakage source.

Therefore, the second embodiment proposes a layout in which the first contact plug 151a is formed in an active region not doped with a P0 layer, but rather includes an N+ connection region 148 that is electrically connected to the N-junction 143.

According to the second embodiment, the electric field is not generated on and/or over the Si surface, which can contribute to reduction in a dark current of a 3D integrated CIS.

FIG. 15 is a cross-sectional view illustrating an image sensor according to a third embodiment.

The image sensor according to the third embodiment may include a readout circuitry (not shown) in a first substrate 300; an interlayer dielectric 360 over the first substrate 300; an interconnection 350 in the interlayer dielectric 360 electrically connected to the readout circuitry; an image sensing device 410 over the interconnection 350; a trench at a pixel boundary of the image sensing device 410; a second conductive type ion implantation region 430 laser-annealed at sidewalls of the trench; and a device separation region 440 in the trench. The readout circuitry can be similar to that described with respect to FIGS. 3 and 14.

The image sensing device 410 may be a photodiode, but, without being limited thereto, may be a photogate, or a combination of the photodiode and the photogate. Embodiments include a photodiode formed in a crystalline semiconductor layer as an example. However, embodiments are not limited thereto, and may include, for example, a photodiode formed in amorphous semiconductor layer.

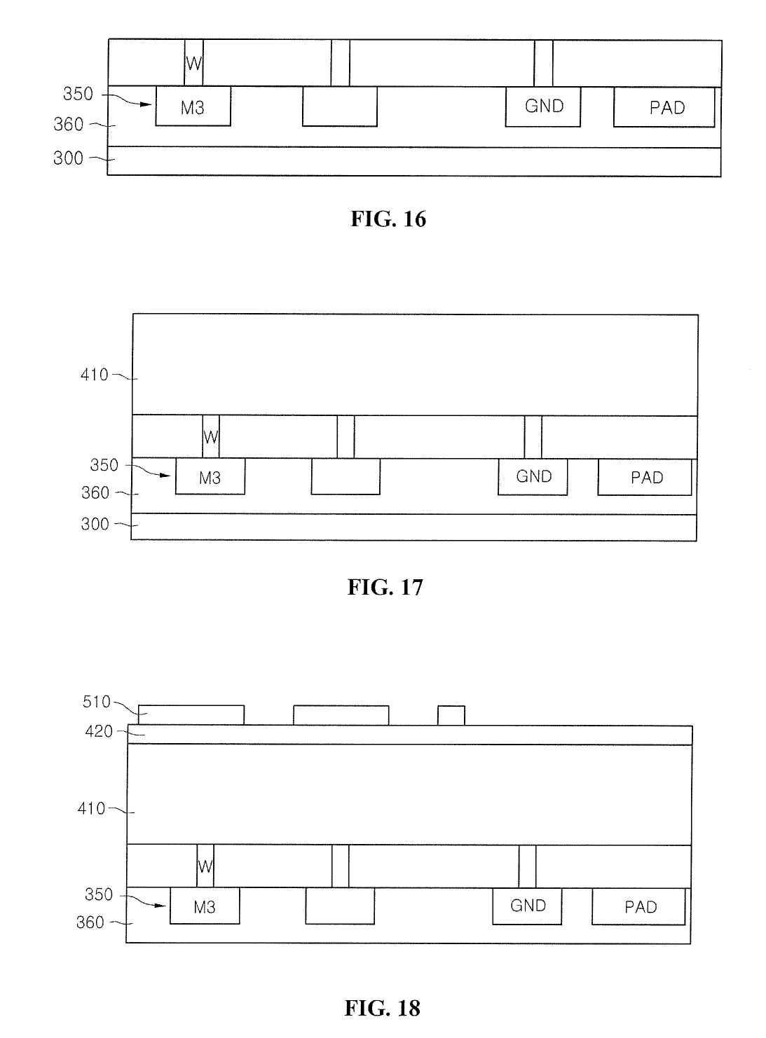

Unexplained reference numerals in FIG. 15 will be described with reference to the drawings illustrating a method for manufacturing the image sensor below. Hereinafter, a method for manufacturing the image sensor according to the third embodiment will be described with reference to FIGS. 16 to 22.

FIG. 16 is a cross-sectional view illustrating a first substrate 300 where an interconnection 350 is formed. Like the first embodiment, the third embodiment may include forming an electrical junction region (not shown) on the first substrate 300 and forming a first conductive connection (not shown) electrically connecting the interconnection 350 to the electrical junction region 140.

Referring to FIG. 17, an image sensing device 410 is formed over the interconnection 350. For example, the image sensing device 410 may be a photodiode formed over a crystalline semiconductor layer. However, embodiments are not limited thereto, and may be, for example, an amorphous silicon-based photodiode. In an embodiment, the image sensing device 410 may be a photodiode including an N+ layer, an N− layer, and a P+ layer in a crystalline semiconductor layer.

In one embodiment, the image sensing device 410 may be formed on a second substrate (not shown) and then bonded to the first substrate. Then, the second substrate is removed leaving the image sensing device over the interconnection 350.

Referring to FIG. 18, a hard mask 420 may be formed over the image sensing device 410, and a photoresist pattern 510 may be formed for defining pixel separation. In an embodiment, the hard mask 420 may be formed of an oxide.

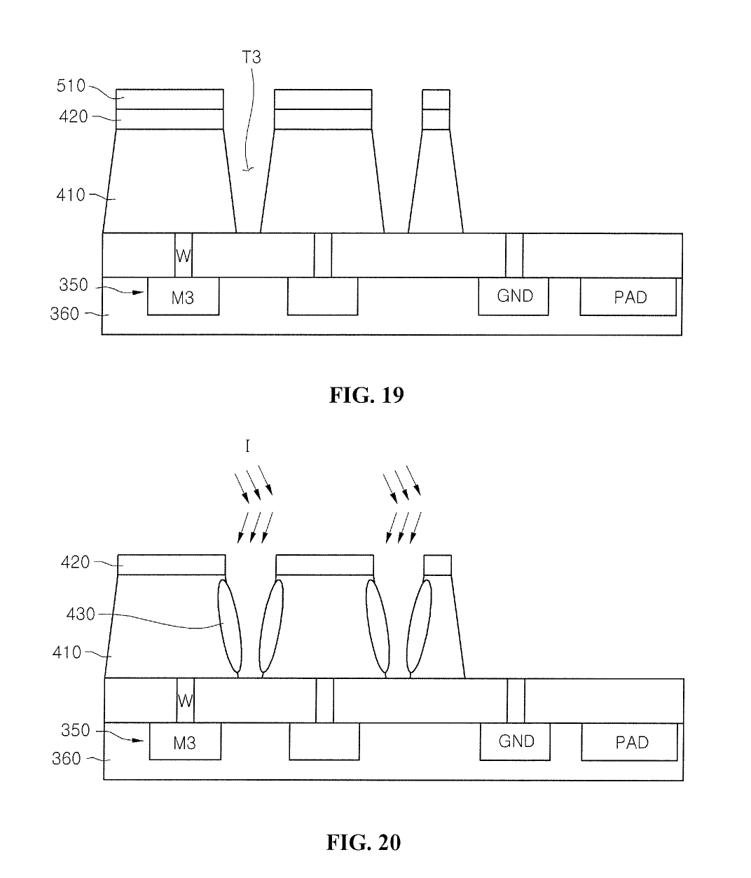

Referring to FIG. 19, a third trench T3 may be formed at a pixel boundary of the image sensing device 410. For example, the third trench T3 may be formed by removing portions of the image sensing device 410 at the pixel boundary of the image sensing device 410 using the photoresist pattern 410 as an etch mask.

As illustrated in FIG. 20, a second conductive type ion implantation region 430 may be formed on the sidewalls of the third trench T3. For example, a P+ ion implantation region 430 of a high concentration (for example, using a dose of about 5×10¹²/cm² to about 5×10¹⁴/cm²) may be formed on the sidewalls of the trench T3. The conductive ion implantation region 430 may use B or BF₂.

Embodiments may further include damaging a surface lattice on the sidewalls of the trench before forming the second conductive type ion implantation region 430 on the sidewalls of the trench. For example, the second conductive type ion implantation region 430 may be thinly formed to secure the electrostatic capacity of the image sensing device. For this, after damaging the surface lattice by ion-implanting GeF₂ before an ion-implantation of the second conductive type ion implantation region 430, B or BF₂ may be ion-implanted. Resulting lattice damage may be recovered by a laser annealing later.

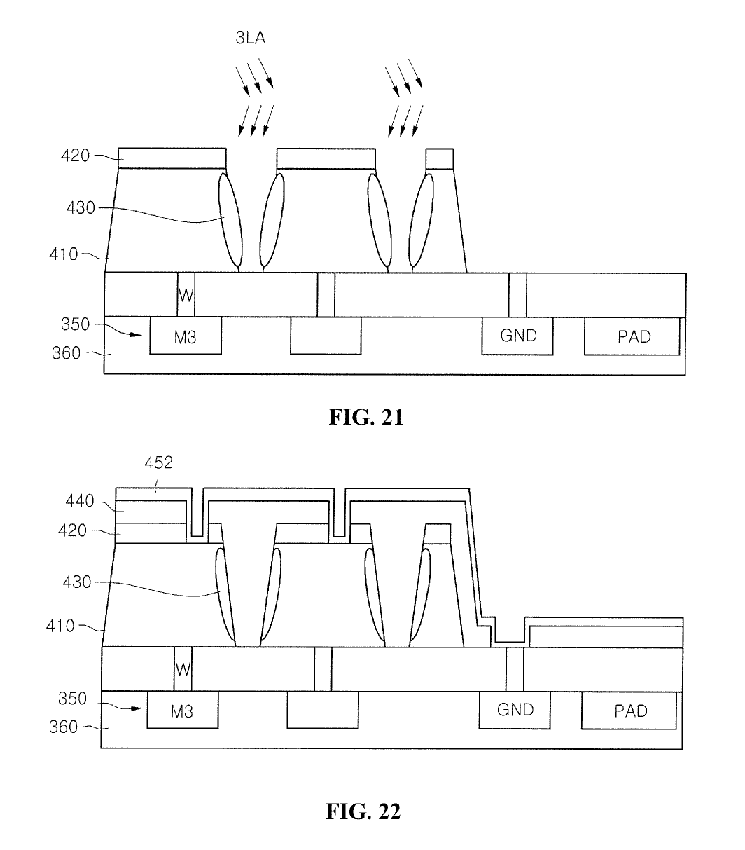

Referring to FIG. 21, a laser annealing may be performed on the second conductive type ion implantation region 430 of the trench T3. For example, the laser annealing may be performed using an energy of about 600 mJ/cm² to about 1200 mJ/cm² to activate the second conductive type ion implantation region 430.

According to the third embodiment, the generation of a dark current may be inhibited at a pixel boundary by removing a dangling bond through a formation of a thin P+ layer on an interface of the pixel boundary of the image sensing device where a crystalline continuity is broken, and a local laser annealing to activate the P− layer.

As illustrated in FIG. 22, a device separation region 440 is formed in the trench where the layer annealing is performed. After this, a process for forming a contact for an upper ground and a process for depositing and patterning a conductor 452 to connect the ground may be performed.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a readout circuitry in a first substrate;
a first interlayer dielectric over the first substrate;
an interconnection in the first interlayer dielectric and electrically connected to the readout circuitry;
a second interlayer dielectric over the first interlayer dielectric;
an image sensing device disposed over the second interlayer dielectric, the image sensing device comprising a first laser annealed trench; and
a contact plug penetrating the first laser annealed trench and the second interlayer dielectric and electrically connecting the image sensing device and the interconnection.

2. The image sensor according to claim 1, further comprising:
a second trench in the image sensing device at a pixel boundary of the image sensing device;
a second conductive type ion implantation region third laser-annealed at sidewalls of the second trench; and
a device separation region in the second trench.

3. The image sensor according to claim 1, further comprising an electrical junction region in the first substrate and electrically connecting the interconnect to the readout circuitry.

4. The image sensor according to claim 3, wherein the electrical junction region comprises:
a first conductive type ion implantation region in the first substrate; and
a second conductive type ion implantation region over the first conductive type ion implantation region.

5. The image sensor according to claim 3, wherein the readout circuitry has a potential difference between a source and a drain of a transistor, the electrical junction region being at the source of the transistor.

6. The image sensor according to claim 3, wherein the electrical junction region is a PN junction.

7. The image sensor according to claim 3, further comprising a first conductive connection between the electrical junction region and the interconnection.

8. The image sensor according to claim 7, wherein the first conductive connection is electrically connected to the interconnection at an upper part of the electrical junction region.

9. The image sensor according to claim 7, wherein the first conductive connection is at one side of the electrical junction region and electrically connects the interconnection to the electrical junction region.

10. An image sensor comprising:
a readout circuitry in a first substrate;
an interlayer dielectric over the first substrate;
an interconnection in the interlayer dielectric and electrically connected to the readout circuit;
an image sensing device over the interconnection;
a trench at a pixel boundary of the image sensing device;
a second conductive type ion implantation region laser-annealed on sidewalls of the trench; and
a device separation region in the trench.

11. The image sensor according to claim 10, further comprising an electrical junction region electrically connected to the readout circuitry over the first substrate.

12. The image sensor according to claim 11, wherein the electrical junction region comprises:
a first conductive type ion implantation region in the first substrate; and
a second conductive type ion implantation region over the first conductive type ion implantation region.

13. The image sensor according to claim 11, wherein the readout circuitry has a potential difference between a source and a drain of a transistor, the electrical junction region being at the source of the transistor.

14. The image sensor according to claim 11, further comprising a first conductive connection between the electrical junction region and the interconnection.

15. A method for manufacturing an image sensor, comprising:
forming a readout circuitry in a first substrate;
forming a first interlayer dielectric over the first substrate;
forming an interconnection in the first interlayer dielectric and electrically connected to the readout circuitry;
forming a second interlayer dielectric over the interconnection;
forming an image sensing device over the second interlayer dielectric;
forming a first trench penetrating the image sensing device;
performing a first laser annealing on sidewalls of the first trench;
forming a contact plug in the first laser annealed first trench; and
forming an insulating layer over the contact plug in the first trench.

16. The method according to claim 15, further comprising, after the forming of the contact plug, performing a second laser annealing on the sidewalls of the first trench.

17. The method according to claim 15, further comprising, after the forming of the image sensing device:
forming a second trench in the image sensing device at a pixel boundary of the image sensing device;
performing a third laser annealing on sidewalls of the second trench; and
forming a device separation region in the third laser-annealed second trench.

18. The method according to 17, further comprising, after the forming of the second trench, forming a second conductive type ion implantation region on the sidewalls of the second trench.

19. The method according to claim 18, further comprising damaging a surface lattice of the sidewalls of the second trench between the forming of the second trench and the forming of the second conductive ion implantation region.

20. The method according to claim 15, further comprising forming an electrical junction region electrically connected to the readout circuitry in the first substrate.
